(19) United States
(12) Patent Application Publication
(10) Pub. No.: US 2026/0293526 A1
(43) Pub. Date: Sep. 24, 2026

(54) DISAPPEARING POLARIZATION HETERO-SUPERJUNCTION ACOUSTIC SWITCH (DIPHAS)

(71) Applicant: Georgia Tech Research Corporation, Atlanta, GA (US)

(72) Inventor: William Alan Doolittle, Atlanta, GA (US)

(21) Appl. No.: 19/472,903

(22) PCT Filed: Mar. 11, 2024
(86) PCT No.: PCT/US2024/019371

§ 371 Date: Oct. 6, 2025

Related U.S. Application Data
(60) Provisional application No. 63/494,793, filed on Apr. 7, 2023.

(51) Int. Cl. H10N 30/20; H10N 30/80

(52) U.S. Cl. CPC H10N 30/20; H10N 30/80; H10N 30/804

(57) ABSTRACT

An exemplary embodiment of the present disclosure provides a disappearing polarization hetero-superjunction acoustic switch (DiPHAS), comprising a disappearing polarization dopant nitride bulk semiconductor superjunction, a first electrode, a second electrode, and a piezoelectric acoustic transducer. The first electrode can be coupled to a first side of the superjunction. The second electrode can be coupled to the second side of the superjunction. The piezoelectric acoustic transducer can be configured to impart acoustic signals to the superjunction. Actuation of the transducer can cause a flow of electrical current from the first electrode, through the superjunction, and to the second electrode.

### CROSS-REFERENCE TO RELATED APPLICATIONS

This application claims the benefit of U.S. Provisional Application Ser. No. 63/494,793, filed on 7 Apr. 2023, which is incorporated herein by reference in its entirety as if fully set forth below.

### FIELD OF THE DISCLOSURE

The various embodiments of the present disclosure relate generally to semiconductor switches.

### BACKGROUND

Most conventional transistors choke current through thin regions where it is modulated by some form of electric field effect, a short-range force limiting current carrying volume and requiring a control terminal (gate, etc.) that limits electrical isolation, introduces substantial switching losses, and typically limits heat extraction to a single side of the device. These field effect transistors also compromise the doping in the drift regions that are designed to withstand large voltages in the off state. Specifically, minimal doping is preferred for the off state but to prevent excessive conductive losses in the on state, the doping concentration that controls conductivity is selected to be less than optimal for the on state and more than optimal for the off state. Accordingly, there is a need for improved switches that overcome the disadvantages associated with conventional devices. Embodiments of the present disclosure provided such improved switches.

### BRIEF SUMMARY

An exemplary embodiment of the present disclosure provides a disappearing polarization hetero-superjunction acoustic switch (DiPHAS). The DiPHAS can comprise a superjunction, a first electrode coupled to a first side of the superjunction, a second electrode coupled to the second side of the superjunction, and a piezoelectric acoustic transducer configured to impart acoustic signals to the superjunction. Actuation of the transducer can cause a change in flow of electrical current from the first electrode, through the superjunction, and to the second electrode.

In any of the embodiments disclosed herein. The DiPHAS can further comprise a first heat sink mechanically coupled to a third side of the superjunction, and the first heat sink can be configured to dissipate heat from the superjunction.

In any of the embodiments disclosed herein, the DiPHAS can further comprise a second heat sink mechanically coupled to a fourth side of the superjunction opposite the third side, and the second heat sink configured to dissipate heat from the superjunction.

In any of the embodiments disclosed herein, the superjunction may not comprise a gate.

In any of the embodiments disclosed herein, the superjunction may not comprise an optical injection port.

In any of the embodiments disclosed herein, the DiPHAS can further comprise a controller configured to apply a drive signal to the acoustic transducer.

In any of the embodiments disclosed herein, the controller can be configured to generate a preload signal to cause a static strain preload on the superjunction.

In any of the embodiments disclosed herein, the DiPHAS can further comprise an adjustable static strain preload transducer, and the preload signal can be configured to drive the strain preload transducer.

In any of the embodiments disclosed herein, the adjustable strain preload transducer can comprise an electromechanical actuator.

In any of the embodiments disclosed herein, the preload signal can comprise a DC signal superimposed on the drive signal to the piezoelectric acoustic transducer.

In any of the embodiments disclosed herein, the strain preload can exhibit a force on the superjunction in a direction perpendicular to a direction of the flow of electrical current through the superjunction.

In any of the embodiments disclosed herein, the strain preload can exhibit a force on the superjunction in a direction parallel to a direction of the flow of electrical current through the superjunction.

In any of the embodiments disclosed herein, the DiPHAS can further comprise an acoustic feedback transducer, and the controller can be further configured to receive a feedback signal from the acoustic feedback transducer.

In any of the embodiments disclosed herein, the DiPHAS can further comprise a current transducer configured to measure an amount of current flowing through at least one of the first and second electrodes, and the controller can be further configured to receive a signal from the current transducer indicative of the measured amount of current.

In any of the embodiments disclosed herein, the superjunction can be configured to maintain a zero net polarization gradient when the piezoelectric acoustic transducer is not imparting acoustic signals to the superjunction.

In any of the embodiments disclosed herein, the superjunction can be configured such that a magnitude of a net polarization gradient of the superjunction increases in response to application of acoustic signals imparted by the piezoelectric acoustic transducer.

In any of the embodiments disclosed herein, the superjunction can be configured to transition from a zero net polarization gradient when acoustic signals are not imparted to the superjunction by the piezoelectric acoustic transducer to a non-zero net polarization gradient when acoustic signals are imparted to the superjunction by the piezoelectric acoustic transducer.

In any of the embodiments disclosed herein, the DiPHAS can be operated such that current does not flow from the first electrode, through the superjunction, and to the second electrode when the superjunction has the zero net polarization gradient, and current does flow from the first electrode, through the superjunction, and to the second electrode when the superjunction has the non-zero net polarization gradient.

In any of the embodiments disclosed herein, the superjunction can be under a strain preload, and the strain preload can have a magnitude selected to tune the superjunction to a zero net polarization when acoustic signals are not imparted to the superjunction by the piezoelectric acoustic transducer.

In any of the embodiments disclosed herein, the superjunction can comprise one or more III-Nitride semiconductors.

In any of the embodiments disclosed herein, the superjunction can comprise one or more In or Sc alloys.

In any of the embodiments disclosed herein, the superjunction can comprise a ScAlInGaN alloy where any percentage combination of Sc, Al, In, Ga atomic concentrations including 0 to 100% for any element sum to equal the concentration of N atoms.

In any of the embodiments disclosed herein, the superjunction can comprise a plurality of ScAlInGaN alloys.

In any of the embodiments disclosed herein, the superjunction can comprise a plurality of semiconductor layers, and the plurality of semiconductor layers can form a plurality of consecutive heterojunctions.

In any of the embodiments disclosed herein, the superjunction can comprise multiple cycles of bulk-like polarization graded dopant layers by composition grades over a volume repeatedly graded up and down.

In any of the embodiments disclosed herein, the superjunction can comprise a first semiconductor layer doped to a first concentration level and a second semiconductor layer doped to a second concentration level different than the first concentration level.

In any of the embodiments disclosed herein, the superjunction can further comprise a third semiconductor layer doped to a third concentration level, and a fourth semiconductor layer doped to a fourth concentration level different than the third concentration level.

In any of the embodiments disclosed herein, the first, second, third, and fourth concentration levels can be selected such that the superjunction is depleted of free carriers when the DiPHAS is in an off-state.

In any of the embodiments disclosed herein, the third concentration level can be equal to the first concentration level and the fourth concentration level can be equal to the second concentration level.

In any of the embodiments disclosed herein, the superjunction can comprise a plurality of impurities, and the piezoelectric acoustic transducer can be configured to impart acoustic signals to the superjunction to cause a geometrical reconfiguration of at least a portion of the plurality of impurities.

In any of the embodiments disclosed herein, the geometrical reconfiguration can cause a change in a flow of electrical current from the first electrode, through the superjunction, and to the second electrode.

In any of the embodiments disclosed herein, the plurality of impurities can comprise one or more selected from the group consisting of: beryllium, carbon, iron, oxygen, silicon, and germanium.

In any of the embodiments disclosed herein, at least a portion of the plurality of impurities can be located at first geometric configurations when the DiPHAS is in an off-state, and the at least a portion of the plurality of impurities can be located at second geometric configurations when the DiPHAS is in an on-state.

In any of the embodiments disclosed herein, the first geometric configurations can be at interstitial positions between lattice atoms, and the second geometric configurations can be at substitutional positions replacing lattice atoms.

In any of the embodiments disclosed herein, the switch can be capable of providing 10 A to about 1000 A of electrical current at a voltage level of at least 1 kV to about 100 kV, with a conduction loss of about 1.5 to about 150 watts.

Another embodiment of the present disclosure provides a method of operating a switch. The switch can be any of the switches disclosed herein. The method can comprise: operating the switch in an off state, wherein the superjunction is maintained at a zero net polarization when the switch is in the off state; and operating the switch in an on state by applying a drive signal to the piezoelectric acoustic transducer, wherein the drive signal causes the transducer to transmit acoustic signals to the superjunction, causing the superjunction to transition from the zero net polarization in the off state to a non-zero net polarization in the on state.

In any of the embodiments disclosed herein, current may not flow through the superjunction in the off state and current can flow through the superjunction in the on state.

In any of the embodiments disclosed herein, the method can further comprise applying a strain preload to the superjunction to achieve the zero net polarization.

In any of the embodiments disclosed herein, the strain preload can be applied via an electromechanical actuator.

In any of the embodiments disclosed herein, the strain preload can be applied via a DC signal superimposed on the drive signal to the piezoelectric acoustic transducer.

In any of the embodiments disclosed herein, the method can further comprise: monitoring a leakage current when the switch is in the off state; and adjusting a magnitude of the strain preload based on the monitored leakage current.

These and other aspects of the present disclosure are described in the Detailed Description below and the accompanying drawings. Other aspects and features of embodiments will become apparent to those of ordinary skill in the art upon reviewing the following description of specific, exemplary embodiments in concert with the drawings. While features of the present disclosure may be discussed relative to certain embodiments and figures, all embodiments of the present disclosure can include one or more of the features discussed herein. Further, while one or more embodiments may be discussed as having certain advantageous features, one or more of such features may also be used with the various embodiments discussed herein. In similar fashion, while exemplary embodiments may be discussed below as device, system, or method embodiments, it is to be understood that such exemplary embodiments can be implemented in various devices, systems, and methods of the present disclosure.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIG. 1 provides a schematic diagram of a DiPHAS, in accordance with some embodiments of the present disclosure.

FIG. 2 provides a schematic diagram of a DiPHAS, in accordance with some embodiments of the present disclosure.

FIG. 3 provides a plot of total polarization charge vs alloy composition.

### DETAILED DESCRIPTION

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include, but are not limited to, similar components or steps that are developed after development of the embodiments disclosed herein.

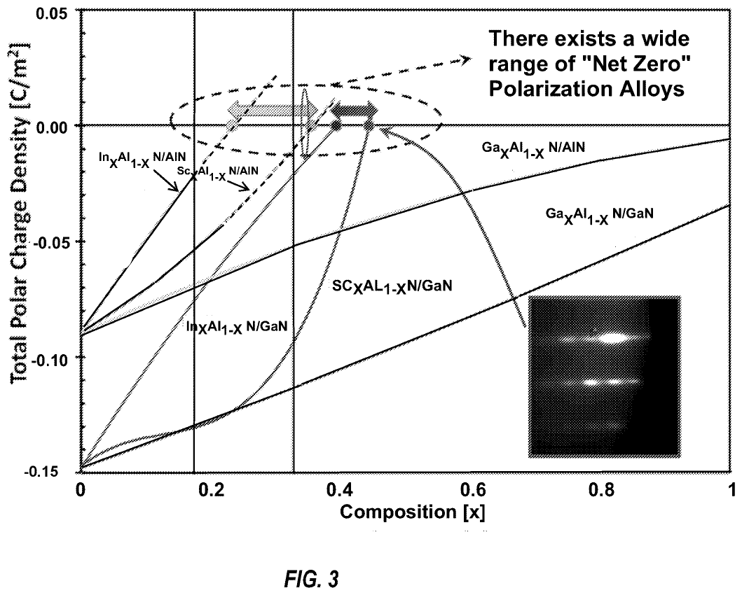

As discussed above, conventional switches employ techniques that cause them to suffer from low voltage isolation, thin channel current constriction, and non-optimal impurity doping to balance the conduction needs in the on and off states. To improve upon these conventional devices, embodiments of the present disclosure can provide an alternative means of transistor modulation, namely acoustic/piezoelectric excitation, which can provide an even better yet unexplored means of obtaining high voltage isolation while also solving the thin channel current constriction and non-optimal static doping issues. This can be achieved, in part, through the use of electronic grade AlInN and AlScN ternary semiconductors. Unlike other III-Nitrides, InScAlGaN alloys can have compositions that result in their piezoelectric polarization (strain induced polarization) offsetting their spontaneous polarization (static unchanging polarization) resulting in zero net polarization (see FIG. 3). Since it is known in the III-Nitride field that mobile charges (electrons and holes) that conduct electricity are attracted to the regions of net polarization, for example forming two dimensional channels in high electron mobility transistors (HEMTs), the absence of this net polarization can lead to the absence of mobile charges needed to carry electricity (See Ibbetson and Jena for examples of 2D electron gas and 3D volume carrier formation as a result of net polar interfaces and bulk regions). Thus, resistive channels can be created by zero net polarization structures. Then, by applying static (for DC on/off) or oscillatory (for high frequency switching) strain to imbalance the polarization through the piezoelectric component of polarization, doped bulk volumes and/or interfaces can be created.

Gauss' Law dictates that this polarization be compensated by attraction of a free charge originating from the electrical contacts and other surfaces and interfaces allowing conduction in the on-state. Using this approach, a normally-off switch can be created wherein polarization dopants appear when strained and disappear when strain is removed. This structure can be implemented in: a) multi-layered 2D sheets formed by consecutive heterojunctions; or b) multiple cycles of bulk-like “polarization graded dopant layers” by composition grades over the volume (repeatedly graded up then down) maintaining at every location the net polarization equal to zero. These zero-polarization but graded composition alloys are possible in In and Sc containing III-Nitride alloys and can result in conducting volumes of arbitrarily large thickness, width, and length not constrained by the short-range extent of the electric field effect used to modulate conductivity in conventional switches. The device blocking voltage can be set by the critical break down field of the extreme bandgap (E_{g}>~5 eV) materials and the length of the device (typically 10-50 μm). When the external strain is added, alternating electron and hole parallel channels can emerge, like a silicon superjunction transistor but without the need for static doping. Because the doping appears and disappears in response to applied external strain, the normal compromises in doping found in traditional field effect transistors are not present. Specifically, there can be no doping present in the off state leading to very large voltage capability. Likewise, in the on-state, substantial doping can be present throughout the entire volume of the semiconductor, not merely a constrictive channel, making the on-state conduction losses substantially less than possible in field effect transistors.

Disclosed herein is a new concept in power switching that can utilize the piezoelectric properties of non-traditional III-Nitride semiconductors to achieve a switch that is isolated from power via acoustic coupling. Unlike conventional transistor implementations, the Disappearing Polarization, Hetero-superjunction Acoustic Switches (DiPHAS) disclosed herein can utilize the entirety of the semiconductor volume for current transport, thus achieving remarkable current/power capability. Via the III-Nitride piezoelectric effect, acoustic mechanical energy delivered from an isolated ultrasonic acoustic actuator can be converted to channel charge allowing high power switching. To accomplish this, embodiments of the present disclosure can comprise III-Nitride alloys that can result in zero net polarization allowing a blocking voltage to be supported in the off-state. Without this net zero polarization feature, current would flow in the off state which is less desirable for a power electronic switch.

Comparison to the State-of-the-Art: As summarized in Table 1 (below) for a specific 10 kVolt/10 amp DiPHAS design, in comparison to the present state-of-the-art, the DiPHAS approaches disclosed herein can be superior in conduction volume and thus lower resistance and heat dissipation; can have dramatically lower conduction and switching losses; can have a control signal that is acoustically isolated from high voltage; can use high impedance piezoelectric drives so as to be immune to noise, electromagnetic interference, and false triggers; can be used for bidirectional switching because they can be symmetric; can allow heat removal from more than one side of the device (doubling its heat dissipation capacity); can have uniform electric field distributions along the device length avoiding high field spikes that lead to premature device breakdown in conventional field effect devices; and can be scaled to very high voltages/currents limited only by packaging constraints which are well known. Switching losses can be similar to but less than other conventional superjunction devices.

TABLE 1

| | | | | 6.5 kV |
|---|---|---|---|---|
| State of the Art | | 6.5 kV SiC | 6.5 kV | Optical |
| Comparison | DiPHAS | DMOSFET | IGBT | IGBT |
| Conduction | 3D | 2D | | |
| Volume | | | | |
| Conduction | ~15 mΩ | 100-300 mΩ | ~15 mΩ 37 Watts | |
| Losses | 1.5 watts | 10-30 Watts | | |
| 10 kV/10 A | | | | |
| Design | | | | |
| Switching | ~0.3 mJ/cycle | ~6.7 mJ/cycle | ~100 mJ/cycle | |
| Losses | to ~5.4 | | | |
| | mJ/cycle | | | |
| Control Isolated | Yes- | No | | Yes - Optically |
| from High | Acoustically | | | |
| Voltage? | | | | |
| Noise Immune | Yes - High | No | | Yes - |
| to False | Impedance | | | Modestly |
| Trigger? | Gate | | | |
| Bidirectional | Yes | No | | |
| Switching? | | | | |
| Package | 2-sided >200 | 1-sided | | |
| Limited Heat | W/cm² | 100 W/cm² | | |
| Removal | | | | |
| Scalable to 10's | Straightforward | Difficult | | |
| to 100's kV | | | | |
| Uniform Field | Yes - More | No Field | No | |
| across Device | Resilient to | Peaks at Gate | Fields Peak at B-C | |
| Length? | Breakdown | Edge | | |
| Voltage | Yes | No | | |
| Capability | | | | |
| Decoupled from | | | | |
| Doping and On | | | | |
| Resistance? | | | | |
| Improved Heat | Yes, both 10- | Difficult - Vertical Device | | |
| Removal? | 100x shorter | | | |
| | heat path and | | | |
| | Wafer Level | | | |
| | Packaging | | | |
| Positive | Yes - | Yes Unipolar | No | |
| Temperature | Unipolar | Device | | |
| Coefficient | Device | | | |
| | Supports | | | |
| | Natural | | | |
| | Current | | | |
| | Sharing | | | |

The 6.5 kV SiC DMOSFET in Table 1 includes GeneSiC part numbers G2R300MT65-CAL and G2R100MT65-CAL which are only 6.5 kV devices but have similar on resistances to research only 10 kV devices such as the XPM3-10000-3050A from Power America. These 10 kV devices typically have R_{DS-On}~350 mΩ so all comparisons are favorable toward the mosfet. The 6.5 kV IGBT in Table 1 is the Infineon FZ250R65KE3. 15 mΩ based on V_{CE}=3-3.7V @ 250 A rating. At 10 A comparable current as described here, 3V_{CE} drop is inherent. Performance of the 6.5 kV Optical IGBT in Table 1 is assumed to be similar to the electrically triggered 6.5 kV IGBT.

DiPHAS design and modeling: Simplicity of topology and the concomitant device scalability are among the greatest strengths of the disclosed DiPHAS switches. Yet DiPHAS represents a new paradigm for high-power switching for which there currently exists no established theory. The parameters listed in Table 1 for the DiPHAS originate from a 20× increase in conduction volume compared to the state of the art work performed for a single channel (traditional HEMT) ScAIN HEMT by the inventors.

Epitaxial Growth: A risk for DiPHAS is in the epitaxial growth. A low thermal budget, high deposition rate (up to ~10 μm/hour) modified form of MBE process developed by the inventor can be used (disclosed in U.S. Pat. No. 9,142,413, entitled “Methods for Growing a Non-Phase Separated Group-Ill Nitride Semiconductor Alloy,” U.S. Pat. No. 10,526,723, entitled “System and Method for Increasing III-Nitride Semiconductor Growth Rate and Reducing Damaging Ion Flux”). This process has shown state of the art AlN, AlInN, AlScN semiconductors and thick superlattice structures similar to those disclosed herein. The low temperature process can be free from atomic desorption complications, can result in state-of-the-art uniformity and incomparable composition control making ternaries, quaternaries, and composition grades routine, and can even control doping with record ranges (>1×10²⁰ cm⁻³ for p and n-type and semi-insulating dopants) if needed to offset any uncompensated polarization charge. Even with all these capabilities that have no rival in traditional MOCVD or MBE, epitaxial risk can remain high. Specifically, it can be desirable to grow the structures disclosed herein without relaxation at compositions where strain can be very high and intermittently capped to freeze in the strain state.

DiPHAS Fabrication: From a semiconductor fabrication perspective, fabrication of the DiPHAS devices can be relatively simple. It can be desirable to optimize the contacts, especially given the extremely conductive volume-based channels used for DiPHAS. Care can be given to packaging the devices to allow the use of high voltages in a confined space. Field terminations, corrugated surfaces, and AlN encapsulation to bury the high voltage components away from surfaces yet provide an acoustic impedance matched interface, should be accounted among other issues. Further, methods to avoid arcing can be employed to result in a reliable, partial discharge-free final package.

DiPHAS System Integration: With the information obtained from the above design considerations, a microcontroller-based integration can be deployed to monitor and adjust off-state current, temperature drift, read acoustic wave feedback, and control the compressive strain “bias” to ensure proper off state shutoff and to excite the piezoelectric actuator to induce switching acoustic modulation. While substantially higher frequency can be achieved, the exemplary device can employ a conservative 50-100 kHz operation. Switching losses are known to be inversely related to the operational frequency making operation in the 10's of MHz desirable.

As discussed above, the switches disclosed herein can offer many advantages over conventional switches, including, but not limited to, lower conduction loses, better high voltage isolation, scalable to any voltage/power level, enhanced heat removal, lower noise, and electromagnetic false trigger immunity.

Additionally, the switches disclosed herein have many applications, including, but no limited to, smart grids, solid state transformers, DC/DC convertors, and DC/AC convertors from low voltage to utility scale voltages.

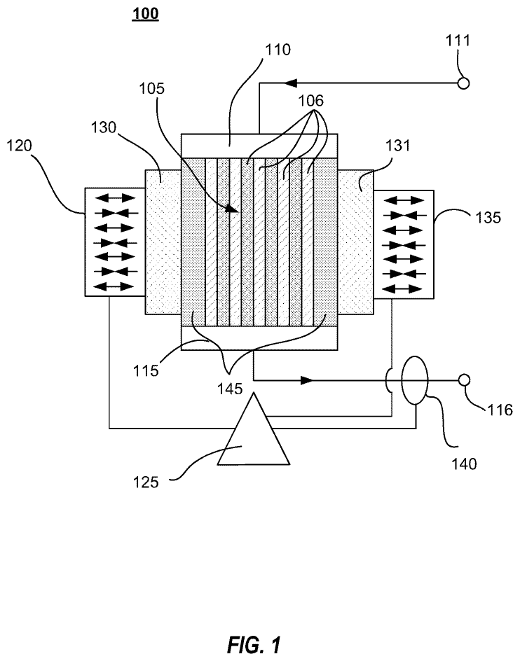

As shown in FIG. 1, some embodiments of the present disclosure provide a disappearing polarization hetero-superjunction acoustic switch (DiPIIAS) 100. The DiPIIAS 100 can comprise a superjunction 105 composed of multiple sub-layers, a first electrode 110 coupled to a first side of the superjunction 105, a second electrode 115 coupled to the second side of the superjunction 105, and a piezoelectric acoustic transducer 120. The piezoelectric acoustic transducer 120 can be configured to impart acoustic signals to the superjunction 105. In particular, actuation of the transducer 120 can cause a change in flow of electrical current from the first electrode 110, through the superjunction 105, and to the second electrode 115.

The change in flow of electrical current through the superjunction 105 can be any of from a non-zero flow to a different (magnitude and/or direction) non-zero current flow, from a zero current flow to a non-zero current flow, or from a non-zero current flow to a zero current flow.

In any of the embodiments disclosed herein, the DiPHAS 100 can further comprise a controller 125 configured to apply a drive signal to the acoustic transducer 120. The controller 125 can be any controller known in the art, including but not limited to, microcontroller, microprocessors, central processing units, and the like. In some embodiments, the controller 125 can comprise one or more sub-controllers configured to carry out various controls disclosed herein. The controller 125 can be located proximate the DiPIIAS 100 or can be remote from the DiPHAS 100.

The superjunction of the DiPHAS 100 can be implemented using multiple technologies disclosed below or combinations of such technologies.

In any of the embodiments disclosed herein, the superjunction 105 can be configured to maintain a zero net polarization gradient when the DiPHAS 100 is in the off-state, such the current is not flowing through the superjunction 105. In some embodiments, when the DiPHAS 100 is implemented as a normally-off switch, the DiPHAS 100 can be in the off-state when the piezoelectric acoustic transducer 120 is not imparting acoustic signals to the superjunction 105 (or only implementing a static strain as discussed below). In other words, the DiPHAS 100 can be operated such that current does not flow from the first electrode 110, through the superjunction 105, and to the second electrode 115 when the superjunction 105 has the zero net polarization gradient, and current does flow from the first electrode 110, through the superjunction 105, and to the second electrode 115 when the superjunction 105 has the non-zero nct polarization gradient.

The zero net polarization structures can be implemented as selections of either abrupt or compositionally graded layers of polar materials provided their spontaneous polarization (static non-changing polarization) is offset by their piezoelectric polarization (strain induced polarization). For example, an AlInN layer with net zero polarization can be either alloyed with or layered next to an AlScN layer with net polarization. If two such net zero polarization materials are alloyed together, a compositional grade (AlScN)ₓ(AlInN)₁₋ₓ where x is varied along the growth direction of the structure could be implemented. Any such structure, 2D layers, alloys of zero net polarization or compositional grades of zero net polarization semiconductors, would have no polarization throughout the semiconductor volume regardless of how many layers or repeated grades (up in composition followed by down in composition) in composition are included. Such a structure would thus be non-conductive when no strain is applied. Conversely, when strain is applied, for example by a DC preload transducer or by an AC acoustic transducer, an unbalancing of the spontaneous to piezoelectric strain occurs resulting in a net polarization. Because adjacent layers (2D layers of AlInN and AlScN in this example or 3D composition grades of the same alloys) would have differing polarizations as a function of position along the growth direction owing to different piezoelectric coefficients, a net polar discontinuity (2D layered case) or net polar grade (alloyed case with compositional grades) would be formed which would attract mobile charges from the contacts or other interfaces (like surfaces). Thus, when strained beyond the state needed to achieve net zero polarization, a net polarization state is created leading to conduction throughout the volume of the semiconductor.

The magnitude of the net polarization gradient of the superjunction 105 can vary in accordance with a magnitude and/or frequency of the acoustic signals imparted to the superjunction 105 by the piezoelectric transducer. For example, superjunction 105 can have a zero net polarization when acoustic signals are not imparted to the superjunction 105 (other than static strain as discussed below). Further, the superjunction 105 can transition to a non-zero net polarization gradient when acoustic signals are imparted to the superjunction 105 by the piezoelectric acoustic transducer 120.

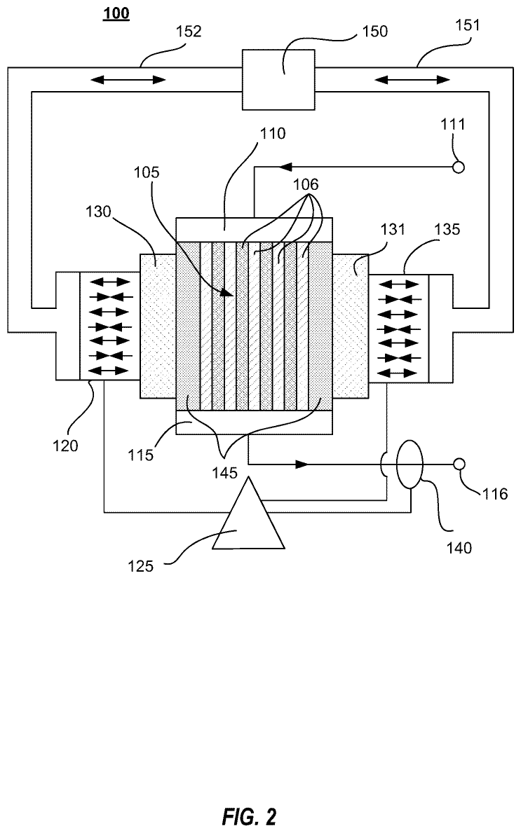

In any of the embodiments disclosed herein, the superjunction 105 can comprise a plurality of semiconductor layers 106. For example, as shown in FIGS. 1-2, the superjunction 105 can comprise a plurality of alternating p-type and n-type semiconductor layers 106, either impurity doped or achieved by polarity discontinuities or grades. The semiconductor layers 106 can form a plurality of consecutive heterojunctions.

The semiconductor layers 106 can be many different semiconductor layers in accordance with various embodiments of the present disclosure. In any of the embodiments disclosed herein, the superjunction 105 can comprise one or more III-Nitride semiconductors. In any of the embodiments disclosed herein, the superjunction 105 can comprise one or more In or Sc alloys. In any of the embodiments disclosed herein, the superjunction 105 can comprise a ScAlInGaN alloy. In any of the embodiments disclosed herein, the superjunction 105 can comprise a plurality of ScAlInGaN alloys.

In any of the embodiments disclosed herein, the superjunction 105 can comprise multiple cycles of bulk-like polarization graded dopant layers by composition grades over a volume repeatedly graded up and down. In some embodiments, the superjunction 105 can be doped to provide carriers (such that the superjunction does not rely solely on receiving carriers via the electrodes). In some embodiments, each layer 106 can be doped to similar or different concentration levels. For example, in some embodiments, the superjunction 105 can comprise a first semiconductor layer doped to a first concentration level and a second semiconductor layer doped to a second concentration level different than the first concentration level. In some embodiments, each of the p-type layers can be doped to the first concentration level and each of the n-type layers can be doped to the second concentration level. Additionally in come embodiments, the p-type layers can each have a different concentration level and the p-type layers can each have a different concentration level. For example, the superjunction 105 can further comprise a third semiconductor layer doped to a third concentration level, and a fourth semiconductor layer doped to a fourth concentration level different than the third concentration level. In some embodiments, the choice of doping of the first, second, third and fourth concentration levels is selected to ensure the overall volume of the semiconductor is depleted of free carriers via the depletion region effect found in traditional homojunction superjunctions examples including superjunctions of Si and SiC materials. However, being that the layered doping occurs in a polar material or in polar heterojunctions, the application of strain will unbalance the depletion effect creating layered doped conductive regions throughout the semiconductor volume. In this way, doped heterojunction superjunctions can be modulated by the external applied strain to modulate current flow.

In some embodiments, the use of doping can be combined with the use of net zero polarization materials to control undesirable conduction originating from naturally occurring defects in the semiconductors. For example, while AlScN can be made resistive, AlInN is often found to be naturally n-type conductive. Thus, its use in a net zero polarization structure could result in undesirable leakage current in the off state. By using traditional p-type (and if needed n-type or semi-insulating) doping, the naturally occurring residual free carrier concentrations of the layers can be neutralized resulting in non-conductive material in the net zero polarization configuration.

In any of the embodiments disclosed herein, the superjunction 105 can comprise a plurality of impurities that are geometrically reconfigurable in response to strain. Specifically, many impurities are found in one geometric location (a particular atomic configuration for example in an interstitial position between lattice atoms) in one strain state and found in a reconfigured geometric position (for example in a substitutional position replacing lattice atoms) under other strain states. Since the electrical activity (leading to conduction or insulation) is impacted by the geometric position of the impurity, this strain induced conduction effect can be used instead of or in conjunction with the zero net polarization and doping superjunction approaches. Defects known to reconfigure under various strain states include Be, Fc, C, O, Si and Ge in III-Nitrides including GaN and AlN as well as ScInAlGaN. All the impurity elements described above and other similar elements, are known to result in semi-insulating properties in various III-Nitride semiconductors and can thus, be used to improve the off-state insulation. Because these elements result in conductive doping under strain, there is a local polarization around the impurity (net charge near the impurity) maintaining the theme of strain modulated polarization doping, albeit localized polarization in the impurity case.

In such embodiments, the piezoelectric acoustic transducer 120 can be configured to impart acoustic signals to the superjunction 105 to cause a geometrical reconfiguration of at least a portion of the plurality of impurities. The geometrical reconfiguration can cause a change in a flow of electrical current from the first electrode 110, through the superjunction 105, and to the second electrode 115. In any of the embodiments disclosed herein, the plurality of impurities can comprise one or more selected from the group consisting of: beryllium, carbon, iron, oxygen, germanium, and silicon, among similar elements.

In some embodiments, a strain preload can be applied to the superjunction 105. In some embodiments, the strain preload can be used to achieve net zero polarization gradient across the superjunction 105. For example, for a normally off DiPHAS, a strain preload can be applied to the superjunction 105 to achieve a zero net polarization gradient across the superjunction 105 so that current does not flow through the superjunction 105. The preload strain applied by an external force can adjust the piezoelectric component of polarization to cancel the spontaneous polarization component to achieve the net zero polarization condition. The magnitude of the static strain preload can be selected to tune the superjunction 105 to a zero net polarization, for example, when acoustic signals are not imparted to the superjunction 105 by the piezoelectric acoustic transducer 120. In some embodiments, the controller 125 can be configured to generate a preload signal to cause a static strain preload on the superjunction 105.

The strain preload can be accomplished a number of ways in accordance with various embodiments of the present disclosure. For example, in some embodiments, the preload strain can be induced by applying a DC signal superimposed on the drive signal to the piezoelectric acoustic transducer 120. The DC signal can impart a static strain from the piezoelectric transducer 120, and the drive signal can then still oscillate around the DC bias to alter the net polarization across the superjunction 105 (to non-net zero) to control current flow.

In some embodiments, as shown in FIG. 2, the DiPHAS can further comprise an adjustable static strain preload transducer, such as an electromechanical actuator 150, and the preload signal can be configured to drive signal the strain preload transducer. For example, the electromechanical actuator 150 can move arms 151 152 relative to the superjunction 105 to apply a force to the superjunction 105. In FIG. 2, the static strain preload can exhibit a force on the superjunction 105 in a direction perpendicular to a direction of the flow of electrical current through the superjunction 105. Alternatively, or additionally, in some embodiments, the static strain preload can exhibit a force on the superjunction 105 in a direction parallel to a direction of the flow of electrical current through the superjunction 105. This later embodiment may be useful in embodiments where the superjunction 105 comprises a geometrically reconfigurable impurities as discussed above.

Additionally, in some embodiments, the static strain preload can be achieved by a combination of a DC bias on the acoustic transducer 120 and a separate electromechanical actuator 150.

In other embodiments, as shown in FIG. 2, a ridged static clamp structure represented by an immovable form of the combination of elements 150, 151 and 152 can be applied such that all acoustic signals applied to the DiPHAS result in strain and not physical displacement. Electromechanical actuator 150 can actuate movement of members 151 and 152 to alter a distance between members 151 and 152 to apply a static strain preload. This ridged structure ensures all applied acoustic forces result in strain and not displacement and prevents certain acoustic resonance modes that are undesirable and could result in device fracture from excessive movement.

In any of the embodiments disclosed herein, the DiPIIAS 100 may not comprise a gate and/or an optical injection port. The absence of these components can assist with heat dissipation from the DiPHAS 100. In particular, the DiPHAS's disclosed herein can include one or more heat sinks 130 131 in locations where gates and/or optical injection ports may be located in conventional switches. The heat sinks 130 131 can be many different heat sinks known in the art. For example, as shown in FIGS. 1-2, in some embodiments, the DiPHAS can comprise a first heat sink 130 mechanically coupled to a third side of the superjunction 105 and configured to dissipate heat from the superjunction 105. In some embodiments, as shown in FIGS. 1-2, the DiPHAS can further comprise a second heat sink 131 mechanically coupled to a fourth side of the superjunction 105 opposite the third side and configured to dissipate heat from the superjunction 105. In addition to the first and/or second heat sinks 130 131, in some embodiments, the DiPHAS can include additional heat sinks and additional sides of the DiPHAS. Additionally, the location of the first and/or second heat sinks 130 131 is not limited to those locations shown in FIGS. 1-2; rather, as those skilled in the art would understand, the first and/or second heat sinks 130 131 can be located at many locations about the DiPHAS to allow for heat dissipation from the superjunction 105.

In any of the embodiments disclosed herein, the DiPIIAS 100 can further comprise an acoustic feedback transducer 135, and the controller 125 can be further configured to receive a feedback signal from the acoustic feedback transducer 135. The acoustic feedback transducer 135 can be utilized to monitor acoustic signals imparted to the superjunction 105 and to infer the applied strain.

In any of the embodiments disclosed herein, the DiPHAS 100 can further comprise a current transducer 140 configured to measure an amount of current flowing through at least one of the first and second electrodes 110 115. For example, the current transducer 140 can be positioned between a contact point 111 116 and the respective electrode 110 115. The controller 125 can be further configured to receive a signal from the current transducer 140 indicative of the measured amount of current. The current transducer 140 can be used, for example, to monitor leakage current through the DiPHAS 100 in the off-state, and the static strain preload can be adjusted to reduce/eliminate the leakage current.

In any of the embodiments disclosed herein, the DiPHAS can further comprise a casing 145 enclosing at least a portion of the superjunction. The casing can be made from many materials known in the art, including, but not limited to, aluminum nitride, silicon nitride, silicon dioxide, various ceramic materials, various polymer materials, and the like.

Another embodiment of the present disclosure provides a method of operating a switch. The switch can be any of the switches disclosed herein. The method can comprise: operating the switch in an off state, wherein the superjunction is maintained at a zero net polarization when the switch is in the off state; and operating the switch in an on state by applying a drive signal to the piezoelectric acoustic transducer, wherein the drive signal causes the transducer to transmit acoustic signals to the superjunction, causing the superjunction to transition from the zero net polarization in the off state to a non-zero net polarization in the on state.

In any of the embodiments disclosed herein, current may not flow through the superjunction in the off state and current can flow through the superjunction in the on state.

In any of the embodiments disclosed herein, the method can further comprise applying a strain preload to the superjunction to achieve the zero net polarization. The static strain preload can be applied using any of the techniques described above, including, but not limited to, via an electromechanical actuator, or a DC signal superimposed on the drive signal to the piezoelectric acoustic transducer.

In any of the embodiments disclosed herein, the method can further comprise: monitoring a leakage current when the switch is in the off state; and adjusting a magnitude of the strain preload based on the monitored leakage current.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way.

1. A disappearing polarization hetero-superjunction acoustic switch (DiPHAS) comprising:
a superjunction;
a first electrode coupled to the superjunction; and
a second electrode coupled to the superjunction;
wherein:
imparting acoustic signals to the superjunction causes a change in a flow of electrical current from the first electrode, through the superjunction, and to the second electrode.

2. The DiPHAS of claim 1 further comprising:
an acoustic transducer configured to impart acoustic signals to the superjunction.

3. The DiPHAS of claim 2 further comprising:
a first heat sink mechanically coupled to the superjunction and configured to dissipate heat from the superjunction.

4. The DiPHAS of claim 3 further comprising:
a second heat sink mechanically coupled to the superjunction and configured to dissipate heat from the superjunction.

5. The DiPHAS of claim 2, wherein at least one of:
the superjunction does not comprise an optical injection port; or
the superjunction does not comprise a gate.

6. The DiPHAS of claim 2 further comprising:
a controller configured to apply a drive signal to the acoustic transducer.

7. A disappearing polarization hetero-superjunction acoustic switch (DiPHAS) comprising:
a superjunction;
a piezoelectric acoustic transducer configured to impart acoustic signals to the superjunction; and
a controller configured to:
apply a drive signal to the piezoelectric acoustic transducer; and
generate a preload signal to cause a static strain preload on the superjunction;
wherein:
actuation of the piezoelectric acoustic transducer causes a change in a flow of electrical current through the superjunction.

8. The DiPHAS of claim 7 further comprising at least one of:
an adjustable strain preload transducer, wherein the preload signal is configured to drive the adjustable strain preload transducer;
a first electrode coupled to a first side of the superjunction, a second electrode coupled to the second side of the superjunction, and a current transducer configured to measure an amount of current flowing through at least one of the first and second electrodes, wherein the controller is further configured to receive a signal from the current transducer indicative of the measured amount of current;
a heat sink mechanically coupled to a third side of the superjunction and configured to dissipate heat from the superjunction;
a rigid clamp comprising first and second members positioned on opposing sides of the DiPHAS; or
an acoustic feedback transducer, wherein the controller is further configured to receive a feedback signal from the acoustic feedback transducer.

9. The DiPHAS of claim 8, wherein at least one of:
the adjustable strain preload transducer comprises an electromechanical actuator;
the preload signal comprises a DC signal superimposed on the drive signal to the piezoelectric acoustic transducer;
the adjustable strain preload transducer is configured to exhibit a force on the superjunction in a direction perpendicular to a direction of the flow of electrical current through the superjunction; or
the adjustable strain preload transducer is configured to exhibit a force on the superjunction in a direction parallel to a direction of the flow of electrical current through the superjunction.

10. (canceled)

11. The DiPHAS of claim 7 further comprising:
a rigid clamp comprising first and second members positioned on opposing sides of the DiPHAS; and
an electromechanical actuator coupled to the first and second members;
wherein:
the preload signal is configured to actuate the electromechanical actuator to alter a distance between the first and second members.

12.-16. (canceled)

17. The DiPHAS of claim 7, wherein at least one of:
the superjunction is configured to maintain a zero net polarization gradient when the piezoelectric acoustic transducer is not imparting acoustic signals to the superjunction;
the superjunction is configured such that a magnitude of a non-zero net polarization gradient of the superjunction increases in response to imparted acoustic signals by the piezoelectric acoustic transducer; or
the superjunction is configured to range between a zero net polarization gradient when the piezoelectric acoustic transducer is not imparting acoustic signals to the superjunction and a non-zero net polarization gradient of the superjunction increases in response to imparted acoustic signals by the piezoelectric acoustic transducer.

18.-20. (canceled)

21. The DiPHAS of claim 7, wherein:
the superjunction is under a strain preload having a magnitude selected to tune the superjunction to a zero net polarization gradient when the piezoelectric acoustic transducer is not imparting acoustic signals to the superjunction.

22. The DiPHAS of claim 7, wherein the superjunction comprises:
one or more III-Nitride semiconductors;
one or more In or Sc alloys;
a ScAlInGaN alloy; or
ScAlInGaN alloys.

23.-25. (canceled)

26. The DiPHAS of claim 7, wherein:
the superjunction comprises:
semiconductor layers forming consecutive heterojunctions;
cycles of bulk-like polarization graded lavers by composition grades over a volume repeatedly graded up and down; or
a first semiconductor layer doped to a first concentration level and a second semiconductor layer doped to a second concentration level different than the first concentration level.

27.-28. (canceled)

29. The DiPHAS of claim 7, wherein:
the superjunction comprises:
a first semiconductor layer doped to a first concentration level;
a second semiconductor layer doped to a second concentration level different than the first concentration level;
a third semiconductor layer doped to a third concentration level; and
a fourth semiconductor layer doped to a fourth concentration level different than the third concentration level; and
the first, second, third, and fourth concentration levels are selected such that the superjunction is depleted of free carriers when the DiPHAS is in an off-state.

30. (canceled)

31. The DiPHAS of claim 29, wherein;
the third concentration level is equal to the first concentration level and the fourth concentration level is equal to the second concentration level.

32. The DiPHAS of claim 7, wherein:
the superjunction comprises impurities, at least a portion of which are geometrically reconfigurable by acoustic signals imparted by the piezoelectric acoustic transducer.

33. The DiPHAS of claim 32, wherein at least one of:
geometrical reconfiguration of the at least portion of the impurities causes the change in the flow of electrical current, through the superjunction;
the impurities comprises one or more elements selected from a group consisting of beryllium, carbon, iron, oxygen, silicon, and germanium; or
the at least a portion of the impurities are located at first geometric configurations at interstitial positions between lattice atoms when the DiPHAS is in an off-state, and at second geometric configurations being substitutional positions replacing lattice atoms when the DiPHAS is in an on-state.

34.-36. (canceled)

37. The DiPHAS of claim 7, wherein:
the DiPHAS is configured to provide a range of from about 10 A to about 1000 A of electrical current at a voltage level in a range of from about 1 kV to about 100 kV with a conduction loss in a range of from about 1.5 watts to about 150 watts.

38.-46. (canceled)

47. A disappearing polarization hetero-superjunction acoustic switch (DiPHAS) comprising:
a superjunction;
a piezoelectric acoustic transducer; and
a controller configured to transition the superjunction between:
a zero net polarization gradient where there is no flow of electrical current through the superjunction; and
a non-zero net polarization gradient where there is a flow of electrical current through the superjunction via actuation of the piezoelectric acoustic transducer to impart acoustic signals to the superjunction.
